(19) United States
(12) Patent Application Publication
(10) Pub. No.: US 2007/0224365 A1
(43) Pub. Date: Sep. 27, 2007

(54) High pretilt homogeneous alignment and tilted vertical alignment by surface modification of thin films with nitrogen ion beam

(76) Inventors: Alessandro C. Callegari, Yorktown Heights, NY (US); James P. Doyle, Bronx, NY (US); Alfred Grill, White Plains, NY (US); Hideo Kimura, Ohtsu-shi (JP); Minhua Lu, Mohegan Lake, NY (US); Vishnubhai V. Patel, Yorktown Heights, NY (US); James Vichiconti, Peekskill, NY (US); Takeshi Yamada, Shiga-ken (JP)

Correspondence Address: David Aker, 23 Southern Road, Hartsdale, NY, 10530, US

(21) Appl. No.: 11/387,323

(22) Filed: Mar. 22, 2006

(51) Int. Cl. C09K 19/00; C23C 16/26; C08J 7/18

(52) U.S. Cl. 428/1.1; 427/553; 427/249.7

(57) ABSTRACT

A method for providing an alignment surface for liquid crystal molecules in a liquid crystal display, comprising depositing on an optically transparent substrate an optically transparent film; and irradiating the film with nitrogen ions sufficiently to produce a pretilt angle of preferably greater than ten degrees. The film is preferably comprised of diamond like carbon. A liquid crystal display formed in accordance with the method.

### BACKGROUND OF THE INVENTION

1. Field of the Invention

The present invention relates to the alignment of liquid crystals. More particularly, it is related to the use of a low energy ion beam to treat inorganic films in order to align liquid crystal molecules, and in particular for the alignment of such molecules in liquid crystal displays.

2. Background Art

A pretilt angle, the angle relative to the substrate plane or normal of the substrates, is required in liquid crystal displays to avoid degeneracy in tilt of the liquid crystal molecules to obtain uniform alignment. Very high pretilt alignment (pretilt angles greater than 10 degree) for liquid crystals has been a challenge to achieve. For most of the known alignment materials and processes, either very high pretilt angles cannot be obtained, or the quality and the stability of such alignment is poor. For vertical alignment (i.e. liquid crystal molecules aligned perpendicular to the surface of the substrates), a stable, uniform, and tilted vertical alignment is difficult to obtain as well. Oblique evaporation of SiO₂ can produce tilted vertical alignment of approximately 2-3 degrees from the substrate normal. However, the range of the pretilt is small and scale up to larger substrates is difficult.

U.S. Pat. Nos. 6,195,146; 6,124,914; 6,346,975; all assigned to the assignee of the present invention; teach various techniques for producing alignment layers in liquid crystal displays, and liquid crystal displays made with such alignment layers. The teachings of these patents is incorporated herein generally, and more specifically, as noted below.

In U.S. Pat. No. 6,195,146, a liquid crystal display cell includes a first substrate; a second substrate; a liquid crystal layer of liquid crystal molecules disposed between the first substrate and the second substrate; a first alignment layer disposed between the first substrate and the liquid crystal layer; and a second alignment layer disposed between the second substrate and the liquid crystal layer. A surface of at least one alignment layer is bombarded by a particle beam of an adjustable energy using a voltage less than 200 volts so that the liquid crystal molecules proximate the surface are induced to a predetermined pretilt angle.

U.S. Pat. No. 6,124,914 teaches a method of generating a patterned alignment direction on an alignment surface for a liquid crystal display cell. The cell is formed by forming a first alignment direction on an alignment surface, such as a polyimide surface of the cell. A second alignment direction is formed on the alignment surface. The first and second alignment directions are formed by a variety of sequences of treatments. An example of a first sequence is a first step of rubbing the alignment surface and thereafter a second step of selectively exposing (preferably using a mask) the alignment surface to a treatment selected from exposure to electromagnetic radiation and exposure to a particle beam. Another example of a sequence is a first step of exposing the alignment surface to a treatment selected from electromagnetic radiation and a particle beam and thereafter selectively exposing (preferably through a mask) the alignment surface to another particle beam.

In U.S. Pat. No. 6,346,975, a liquid crystal display device has first and second substrates, a first electrode layer overlying one surface of the first substrate, and a second electrode layer overlying one surface of the second substrate. A first alignment layer overlies the first electrode layer, and a second alignment layer overlies the second electrode layer, and a liquid crystal material is disposed between the alignment layers. In one preferred embodiment, each alignment layers is a polyimide layer. This patent also teaches a method for manufacturing a liquid crystal display device. According to the method, first and second substrates are provided, a first electrode layer is deposited over the first substrate, and a second electrode layer is deposited over the second substrate. A first alignment layer is deposited over the first electrode layer, and a second alignment layer is deposited over the second electrode layer. The first and second substrates are arranged so that the alignment layers face one another and a space is formed between the substrates. A liquid crystal material is disposed in the space between the first and second substrates.

However, in further embodiments, various types of films are employed in conjunction with various alignment techniques to form insulating (or poorly conducting) alignment films for the LCD device. Any film that is optically transparent and amorphous or fine grained is said to be suitable. (The term amorphous means that the atomic structure of the film has no preferred direction or orientation.) For example, a suitable alignment film can be formed using: hydrogenated diamond-like carbon (DLC), amorphous hydrogenated silicon, SiC, SiO₂, glass, Si₃N₄, Al₂O₃, CeO₂, SnO₂, or ZnTiO₂. Basically, any type of polymer or monomeric material is used as long as the formed film is optically transparent, particularly in the visible spectrum.

### SUMMARY OF THE INVENTION

It is an object of the invention to provide a cost effective and simple method for producing high pretilt alignment surfaces for liquid crystal molecules in liquid crystal displays.

It is another object of the invention to provide a method for providing alignment surfaces without the need to perform rubbing operations.

It is a further object of the invention to provide liquid crystal displays made in accordance with the method.

In this invention, a method of tuning the pretilt angle from homogeneous to vertical (0-90 degree) by surface modification of a diamond like carbon film through low energy ion beam irradiation is disclosed. This method allows one to obtain a desired pretilt through adjustment of the ion beam process conditions including ion type, energy, dose and incident angle. In addition, it can be easily scaled up for large substrates and mass production.

These objects and others are achieved in accordance with the invention by a method for providing an alignment surface for liquid crystal molecules in a liquid crystal display, comprising: depositing a film on a substrate; and irradiating the film with nitrogen ions sufficiently to produce a pretilt angle of greater than ten degrees. The substrate need not may be transparent in the case of one of the two substrates of a reflection type liquid crystal display. However, in the more common case of transmissive type liquid crystal displays, both the substrates and the films on which the substrates are deposited, are transparent.

The film is preferably comprised of diamond like carbon, with the nitrogen ions having an energy which causes carbon rings of the film with a larger interaction cross section with the ions to have a higher probability of being destroyed than carbon rings with smaller interaction cross sections with the ions. The nitrogen forms carbon-nitrogen bonds in the film, whereby an asymmetry in the orientation of remaining carbon rings is created by the ions. The diamond like carbon may be deposited by PECVD.

The film can be deposited on the substrate at an RF power density of substantially 30 mW/cm². The deposition temperature can be between room temperature and 280° C. A gas precursor of the diamond like carbon film can comprise approximately 5% C₂H₂ and 95% He. Hydrogen can be added to the gas precursor to increase light transmittance of the film. The thickness of the film is preferably between substantially 20 and 100 Å. The method film cam be comprised of an inorganic material, such as CaF₂ and MgF₂, and Al₂O₃. The film may also contain of silicon, carbon, oxygen and hydrogen, and can be formed by using tetramethylcyclotetrasiloxane as a precursor.

Preferably, the energy of the nitrogen ions is less than 200 electron volts, but sufficient to break bonds in the film. The energy of the nitrogen ions can be 100 electron volts. As a practical matter, this may mean that the energy of the nitrogen ions is between 200 electron volts and 75 electron volts, although in some application lower or higher energies may be useful.

An incident angle of irradiation of the film by the nitrogen ions can be within ten degrees to eighty degrees with respect to a normal to the substrate on which the film is deposited. The incident angle of irradiation of the film by the nitrogen ions can be thirty five degrees.

The pretilt angle of the alignment layer can be greater than fifteen degrees, or greater than forty-five degrees.

The invention is also directed to a method for providing an alignment surface for liquid crystal molecules in a liquid crystal display, comprising depositing on a substrate a film comprised of a material selected from the group consisting of CaF₂, MgF₂ and a film containing silicon, carbon, oxygen and hydrogen; and irradiating the film with nitrogen ions sufficiently to produce a pretilt angle.

In accordance with another aspect, the invention is also directed to a liquid crystal display comprising a first substrate; a second substrate; liquid crystal material disposed between the first substrate and the second substrate; and an alignment layer of diamond like carbon disposed on at least one of the first substrate and the second substrate, the alignment layer having a pretilt angle greater than ten degrees.

In accordance with yet another aspect, the invention is directed to a liquid crystal display comprising a first substrate; a second substrate; liquid crystal material disposed between the first substrate and the second substrate; and an alignment layer disposed on at least one of the first substrate and the second substrate, the alignment layer including carbon rings, wherein carbon rings of the film with a larger interaction cross section with bombardment ions have a higher probability of being destroyed than carbon rings with smaller interaction cross sections with the ions, further comprising carbon-nitrogen bonds in the film, whereby an asymmetry in the orientation of remaining carbon rings is created by the ions.

### BRIEF DESCRIPTION OF THE DRAWINGS

The foregoing aspects and other features of the present invention are explained in the following description, taken in connection with the accompanying drawings, wherein:

FIG. 1 illustrates pretilt angle as a function of N ion dose for various samples.

### DETAILED DESCRIPTION OF THE PREFERRED EMBODIMENT

Diamond like carbon (DLC) films are deposited in a PECVD chamber with a gas precursor typically comprised of 5% C₂H₂ and 95% He. Additional H₂ can be added to increase the transmittance of the film. Carbon films are deposited on substrates at an RF power density of about 30 mW/cm2. The deposition temperature can be set from room temperature to 280° C. The thickness of the film is about 20-100 Angstroms.

A collimated low energy N ion beam is incident on the substrate at an oblique angle to the substrates coated with Diamond Like Carbon (DLC) film. Apparatus for producing this ion beam are disclosed in the abovementioned U.S. Pat. No. 6,346,975 and in U.S. Pat. No. 6,020,946, which are both incorporated herein in their entireties.

In the DLC film, the carbon rings with a larger interaction cross section with the ion beam have a higher probability of being destroyed than the rings with smaller cross sections. As a result, an asymmetry in the orientation of the carbon rings is created by the ion beam. This asymmetry is responsible for alignment of the liquid crystal and its pretilt angle. Unlike heavy inert ions such as Ar+, nitrogen ions can react with a carbon film and alter the surface chemistry in addition to the ring breakage. It is found that when the surface of DLC film is modified by nitrogen ions, a very high pretilt angle of 15 degree or greater can be obtained. The shallower the ion beam incident angle and the larger the dose, the higher the pretilt angle.

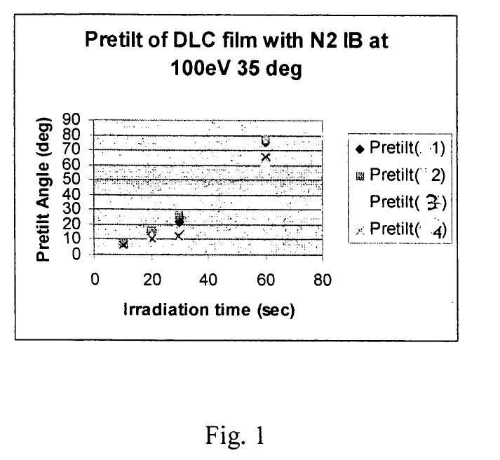

FIG. 1 shows the pretilt angle as a function of N ion dose. It demonstrates that a pretilt angle relative to the substrate from nearly zero up to nearly 90 degree can be obtained by changing the dose of N ion bombardment. Such a dramatic change in pretilt angle is not observed with Ar ion beam irradiation. For N ion beam irradiation, the large pretilt angle cannot be obtained at higher ion energy and steeper incident angle. That means that the surface modification the DLC film with nitrogen ions is most effective at low ion energy and shallow incident angles where the sputtering rate is low. Typical incident angles are in the range of ten to eighty degrees with respect to a normal to the substrate on which the film is deposited.

### Embodiment 1

DLC film is ion beam irradiated with low energy N₂⁺ ions (including a component of N⁺ ions, due to some break up of N₂) at an oblique angle of between ten and eighty degrees, but preferably at thirty-five degrees. The nitrogen ions react with the DLC film forming CN bonds on the surface. The surface energy is reduced in this process resulting in an increase in the pretilt angle. A change of pretilt angle from 2-3 degrees up to 80 degrees is observed.

### Embodiment 2

The inorganic film is comprised of a silicon carbon oxygen hydrogen film (SiCOH) deposited from, for example, a liquid precursor such as tetramethylcyclotetrasiloxane (TMCTS) followed by alignment of the surface using ion beam bombardment with, for example, Ar or N ions in the energy range of a few hundred electron volts. Pretilt angles from 2-10 degree are obtained. The alignment quality is good. In addition to the ion beam irradiation condition, the pretilt angle of the alignment can be tuned by varying the carbon concentration of the film. The higher the carbon concentration, the higher the pretilt angle. Since the structure and composition of the SiCOH film have huge variations and can be easily manipulated, one can tune the SiCOH film for different applications such as higher pretilt angle, low pretilt angle, high photostability etc. For example, a dense SiCOH film with porous structure will give more photo stable alignment.

### Embodiment 3

Inorganic films such as CaF₂ and MgF₂, and Al₂O₃ are treated with collimated ion beams. Homogeneous liquid crystal alignment was obtained. CaF₂ and MgF₂ films can produce pretilt angles up to 10 degrees.

It is noted that for essentially vertical alignment of the liquid crystal display molecules, it is necessary to use a liquid crystal material that exhibits negative dielectric anisotropy.

It should be understood that the foregoing description is only illustrative of the invention. Various alternatives and modifications can be devised by those skilled in the art without departing from the invention. Accordingly, the present invention is intended to embrace all such alternatives, modifications and variances which fall within the scope of the appended claims.

What is claimed is:

1. A method for providing an alignment surface for liquid crystal molecules in a liquid crystal display, comprising:
depositing a film on a substrate; and
irradiating the film with nitrogen ions sufficiently to produce a pretilt angle of greater than ten degrees.

2. The method of claim 1, wherein the film is comprised of diamond like carbon and wherein the nitrogen ions have an energy which causes carbon rings of said film with a larger interaction cross section with the ions to have a higher probability of being destroyed than carbon rings with smaller interaction cross sections with the ions, and the nitrogen forms carbon-nitrogen bonds in the film, whereby an asymmetry in the orientation of remaining carbon rings is created by the ions.

3. The method of claim 1, wherein the film is comprised of diamond like carbon deposited by PECVD.

4. The method of claim 3, wherein the film is deposited on the substrate at an RF power density of substantially 30 mW/cm2.

5. The method of claim 3, wherein deposition temperature is between room temperature and 280° C.

6. The method of claim 1, wherein the film is comprised of diamond like carbon and wherein a gas precursor of the diamond like carbon film comprises approximately 5% C₂H₂ and 95% He.

7. The method of claim 6, further comprising adding hydrogen to the gas precursor to increase light transmittance of the film.

8. The method of claim 1, wherein thickness of the film is between substantially 20 and 100 A.

9. The method of claim 1, wherein the film is comprised of an inorganic material.

10. The method of claim 1, wherein the inorganic material is selected from the group consisting of CaF₂ and MgF₂, and Al₂O₃.

11. The method of claim 1, wherein the film is comprised of silicon, carbon, oxygen and hydrogen.

12. The method of claim 11, wherein the film is formed by using tetramethylcyclotetrasiloxane as a precursor.

13. The method of claim 1, wherein the energy of the nitrogen ions is less than 200 electron volts, but sufficient to break bonds in the film.

14. The method of claim 1, wherein the energy of the nitrogen ions is 100 electron volts.

15. The method of claim 1, wherein an incident angle of irradiation of the film by the nitrogen ions is within ten degrees to eighty degrees with respect to a normal to the substrate on which the film is deposited.

16. The method of claim 1, wherein the incident angle of irradiation of the film by the nitrogen ions is thirty five degrees.

17. The method of claim 1, wherein the pretilt angle of the alignment layer is greater than fifteen degrees.

18. The method of claim 1, wherein the pretilt angle of the alignment layer is greater than forty five degrees.

19. A method for providing an alignment surface for liquid crystal molecules in a liquid crystal display, comprising:
depositing on a substrate a film comprised of a material selected from the group consisting of CaF₂, MgF₂ and a film containing silicon, carbon, oxygen and hydrogen; and
irradiating the film with nitrogen ions sufficiently to produce a pretilt angle.

20. A liquid crystal display comprising:
a first substrate;
a second substrate;
liquid crystal material disposed between said first substrate and said second substrate; and
an alignment layer of diamond like carbon disposed on at least one of said first substrate and said second substrate, said alignment layer having a pretilt angle greater than ten degrees.

21. A liquid crystal display comprising:
a first substrate;
a second substrate;
liquid crystal material disposed between said first substrate and said second substrate;
an alignment layer disposed on at least one of said first substrate and said second substrate, said alignment layer including carbon rings, wherein carbon rings of said film with a larger interaction cross section with bombardment ions have a higher probability of being destroyed than carbon rings with smaller interaction cross sections with the ions, further comprising carbon-nitrogen bonds in the film, whereby an asymmetry in the orientation of remaining carbon rings is created by the ions.
